(19) United States
(12) Patent Application Publication
(10) Pub. No.: US 2017/0013965 A1
(43) Pub. Date: Jan. 19, 2017

(54) HEATING CONTROL SYSTEM FOR HEATED FABRIC DEVICE

(71) Applicant: SIT & HEAT B.V., Wijchen (NL)

(72) Inventors: Paul Schurink, Heerde (NL); Jorg Rijkschroeff, Nijmegen (NL)

(21) Appl. No.: 15/123,953

(22) PCT Filed: Mar. 6, 2015
(86) PCT No.: PCT/EP2015/054779

§ 371 Date: Sep. 6, 2016

(30) Foreign Application Priority Data
Mar. 6, 2014 (NL) NL2012370

(51) Int. Cl. A47C 7/74; H05K 1/18

(52) U.S. Cl. CPC A47C 7/748; H05K 1/189; H05K 2201/10106

(57) ABSTRACT

The current invention concerns a heating control system for regulating a heating system present in a fabric device, such as a cushion for a seat. In a second and third aspect the current invention relates to a fabric device comprising such heating control system and a seat for comprising such fabric device.

### TECHNICAL FIELD

The invention pertains to the technical field of heated cushions, more in particular to the field of heated cushions for seats intended for outdoor use.

### BACKGROUND

Electro-blankets, heating pads, bed warmers, heating mats and the like, hereafter generically referred to as “heating devices” have long been known; they are electrical devices of various sizes that produce and transmit heat to the human body. Typically, these heating devices are provided within them of an electric circuit which, when activated, transmits heat to the user when he/she is in rest conditions, in bed or sitting. Generally, heating pad means a portable fabric device, of smaller dimensions than electro-blankets or bed warmers, such that it can be applied to specific parts of the body, such as on the belly, back, neck or the like.

Typically, such heating devices are constituted by a main body, the outer surface of which is such as to be placed in contact with the human body, and by a heating element positioned within such a main body.

NL 1 039 218 describes a patio heater comprising a seat and heated cushion. The cushion is thereto provided with heating elements, which are connected to an external power supply such as a battery. The heating system can be externally regulated by the user.

EP 2 653 073 describes a heating device having a temperature regulating system comprising a temperature control and adjustment device.

US 2008 0023460 describes a garment provided with a heating system with separate control.

In order to switch the heating system on or off, most of these known systems comprise a common button generally known in the art. The button is connected to the internal heating system of the heating devices (e.g. by means of an electrical wire and plug) as well as to the power supply (e.g. by a socket). Hence, the presence of all these connections presents a serious restraint in the freedom of movement of the user.

There remains a need in the art for improved design of the regulating and control system of heating devices, in order to allow for instance outdoor usage and improve the user friendliness. By preference, the heating control system should be optimized in dimension in order to allow build-in a fabric (even very thin fabric), without it being absolutely apparent to the user. The system should be furthermore easily implementable in the fabric.

There is furthermore also a need to improve the safety of the use of heated devices, by minimizing the necessary cabling and by attaching and/or incorporating the control units as much as possible to or in the fabric device.

### SUMMARY OF THE INVENTION

The present invention provides a heating control system according to claim 1, a fabric device for a seat according to claim 8 and a seat according to claim 12. The heating control system is designed to optimally steer a heating system comprising heating elements present in a fabric device such as a seat cushion. Said heating control system is user friendly, and enlarges the safety of the heating device as the external connections/regulating systems are reduced to a minimum because they are largely internalized in the fabric device. Moreover, the heating control system according to the current invention allows outdoor use of the fabric device without the imminent need of the availability of a fixed power supply.

### DESCRIPTION OF FIGURES

FIG. 1 shows a possible embodiment of a signal transfer module according to the current invention.

FIG. 2 shows a possible embodiment of a heat regulating module according to the current invention.

FIG. 2A shows a possible embodiment of a heat regulating module and a signal transfer module according to the current invention.

FIGS. 3 shows a possible embodiment of a heat regulating module with cover according to the current invention.

FIG. 4 shows a possible embodiment of a heating control system according to the current invention.

FIG. 4A shows a cover a heat regulating module according to an embodiment of the current invention.

FIG. 5A shows a cross section of the fabric and heating control system at the level of the sews. FIG. 5B shows a possible embodiment of the heat regulating module with cover according to the current invention, with schematic detail of the sews used for attaching the heat regulating module to the tissue device.

FIGS. 6 A, B and C shows possible embodiment of a seat provided with a cushion according to a possible embodiment of the current invention.

FIG. 7 shows a possible embodiment of power supply attachment means according to the current invention.

FIG. 8 shows a detail of a possible embodiment of the power supply casing according to the current invention.

FIG. 9 shows the inside of a casing and power supply according to a possible embodiment of the current invention.

FIGS. 10 show a schematic overview of the power supply and casing according to an embodiment of the current invention.

FIGS. 11a and 11b show cross-sectional views of power supply attaching means according to the current invention, engaged to the power supply.

FIG. 12 shows embodiments of a seat according to the current invention.

### DETAILED DESCRIPTION OF THE INVENTION

The present invention concerns a heating control system for regulating a heating system present in a fabric device. Said heating control system is user friendly, and enlarges the safety of the heating device as the external connections/regulating systems are reduced to a minimum. Moreover, the heating control system according to the current invention allows outdoor use of the fabric device without the imminent need of the availability of a fixed power supply.

Unless otherwise defined, all terms used in disclosing the invention, including technical and scientific terms, have the meaning as commonly understood by one of ordinary skill in the art to which this invention belongs. By means of further guidance, term definitions are included to better appreciate the teaching of the present invention.

As used herein, the following terms have the following meanings:

“A”, “an”, and “the” as used herein refers to both singular and plural referents unless the context clearly dictates otherwise. By way of example, “a compartment” refers to one or more than one compartment.

“About” as used herein referring to a measurable value such as a parameter, an amount, a temporal duration, and the like, is meant to encompass variations of +/−20% or less, preferably +/−10% or less, more preferably +/−5% or less, even more preferably +/−1% or less, and still more preferably +/−0.1% or less of and from the specified value, in so far such variations are appropriate to perform in the disclosed invention. However, it is to be understood that the value to which the modifier “about” refers is itself also specifically disclosed.

“Comprise,” “comprising,” and “comprises” and “comprised of” as used herein are synonymous with “include”, “including”, “includes” or “contain”, “containing”, “contains” and are inclusive or open-ended terms that specifies the presence of what follows e.g. component and do not exclude or preclude the presence of additional, non-recited components, features, element, members, steps, known in the art or disclosed therein.

The recitation of numerical ranges by endpoints includes all numbers and fractions subsumed within that range, as well as the recited endpoints.

The expression “% by weight” (weight percent), here and throughout the description unless otherwise defined, refers to the relative weight of the respective component based on the overall weight of the formulation.

In a first aspect, the invention provides for a heating control system for regulating a heating system present in a fabric device, such as a cushion for a seat, and whereby said control system comprises a signal transfer module and a heat regulating module. Said signal transfer module and heat regulating module are connected. Connection may occur by various suitable means known in the art such as by means of a pin cable. In another embodiment, said modules are physically connected on one master module. In a preferred embodiment, said heat regulating module comprises a (flexible) print plate.

For the purpose of the current invention, said heating control system is the system that steers the heating elements present in a heating device upon receiving instructions of either the user and/or sensors present in the heating device. For the purpose of the current invention, said heat regulating module is to be understood as the entity of the heating control system that comprises means for (de)activating said heating system by a user and means for transferring the received instructions from the user to a second entity of the heating control system, e.g. the signal transfer module.

For the purpose of the current invention, said signal transfer module is to be understood as that entity of the heating control system that transfers signals which are received from e.g. the heat regulating module or from sensors to the corresponding heat elements. The heating control system can therefore be seen as steering device for the heating elements.

Said fabric device may be a blanket, a pillow, a cushion, etc. By preference, said fabric device is a seat cushion, comprising a seat part and a back part.

By preference, said print plate comprises electronic circuits mounted on a plastic or polymer substrate. Such substrate may for instance be polyimide, polyester, polyethylenetereftalate, a polyetherketon, polyimide (PI), polyethylene napthalate (PEN), Polyetherimide (PEI), fluropolymers (FEP), copolymers or transparent conductive polyesterfilm. In a preferred embodiment, said print plate has a certain degree of flexibility and can be understood as a flexible print plate or flex circuit.

By preference, said print plate has a thickness between 0.01 and 2 mm, more preferably between 0.05 and 0.5 mm.

Use of a (flexible) print plate allows easy attachment and (partial) internalization of the heat regulating module in the fabric. Because of the small dimensions of the different modules, incorporation in a fabric is easy and barely noticeable to the user. By allowing direct attachment of the heat regulating module to the fabric, a more user-friendly and safer actuating means are offered compared to what is generally known in the art. The amount of necessary wiring visible to the user is minimized or eliminated completely, as they become internalized. Moreover, because of its flexible nature, the heat regulating module will provide more comfort compared to for instance generally known actuating buttons. Lastly, a flexible heat regulating module will generally be perceived as more esthetic compared to commonly known actuating systems.

The pin cable used is preferably an 8 pin cable.

In a further embodiment the print plate is provided with a control processing unit (CPU). To that purpose, the print plate may be provided with a stiffener attached to support the weight of the CPU. Said stiffener comprises preferably a plastic material such as epoxy.

The flexible print plate is by preference provided with one or more touch areas which may (de)activate or regulate said CPU. Such touch areas may comprise known devices in the art such as a button, a knob, or touch buttons. Upon touching or pushing these areas, a user may indicate whether he wants to activate or deactivate the heating system connected to the heating control system. Advantageously the print plate will also be provided with touch areas for regulating the heat system, e.g. for lowering or increasing the desired heat. The latter allows personal regulation of the heat system by the user. In a further embodiment, said flexible print plate comprises one or more LED lights. The latter can indicate whether or not the heating system is activated and/or what the degree of heating is. Said each touch area may comprise between 0.5 and 7% of the total surface of the print plate, more preferably between 1 and 5%.

If a flex circuit is used, said print plate is preferably provided with one or more sewing areas. Preferably said print plate comprises at least two sewing areas, placed on opposite sides of said print plate, said sewing areas are devoid of circuits. The sewing areas are preferably indicated on said print plate, e.g. by symbols, text, an outline or contour, etc. Said sewing area is provided for attaching the heat regulating module to the fabric, e.g. a seat cushion. By preference, said heat regulating module will be partially internalized in the fabric, with the remaining part visible outside the fabric, allowing to be operated by a user. The position and surface of the sewing area(s) is thus determined to allow adequate attachment of the heat regulating module to the fabric, preferably by means of stitches or sews. By indicating the correct sewing areas on the flexible print, one prevents that the heat regulating module is incorrectly sewn into the fabric, thereby risking perturbation of the circuits on the flexible print. The area in between the sewing areas will serve as guidance area for the circuits present on the print plate. By preference, the surface of the sewing area will comprise between 2.5% and 10% of the total surface area of the flexible print plate, more preferably between 5 and 9%. Said sewing areas are preferably placed symmetrical in view of the midline of the print plate. By preference, each of the sewing areas have substantially the same surface.

The print plate will be preferably enveloped by a flexible cover or sleeve. Such cover is preferably made from a silicone material or polymer such as PVC and serves to protect the flexible print plate and allows providing visual instructions to the user which correspond to the functioning of the heating system. By preference, said flexible cover is comprised of symbols or instructions corresponding to said touch areas. For instance, the cover may be provided with the on/off symbol on a position which corresponds to the underlying touch area for (de)activating the heating system. Other visual marks on the cover may comprise e.g. marks for adjusting/amending the heat intensity, for e.g. transmitting a request to a central unit, etc. By preference, said symbols or instructions are provided in relief, such that the user may without looking, operate the module.

The heating control system furthermore comprises a signal transfer module. In a preferred embodiment, said signal transfer module comprises of a printed circuit board. Said signal transfer module comprises preferably connectors for connecting said module to a power supply, one or more heating elements and optionally a sensor system. These connectors serve as distributor. These connectors will receive signals/current from the heat regulating module (as well as from potentially present sensors) and will on its turn transfer signals to the end components of the heating system, e.g. the heating units present in the fabric device.

The fabric device may be provided with one or more sensors, which redirect signals to the signal transfer module, which on its turn may transfer the latter to the heating elements present in the fabric.

The signal transfer module hence allows switching the heating elements present in the fabric device. In the case where the fabric device is a seat cushion, such heating elements may be present in both the seating part as the back part. Hence, the signal transfer module should comprise connectors for switching the seating part as well as the back part.

By preference, said switching occurs by means of one or more transistors present on printed circuit board of said signal transfer module. In a further preferred embodiment, said transistor is a field effect transistor (FET), more preferably a Metal-Oxide-Semiconductor Field-Effect Transistor or MOSFET.

In a second aspect, the current invention provides for a fabric device, in the current invention preferably a cushion for an (outdoor) seat or a cover for a seat which is comprised of a heating control system as described above. By preference, such cushion comprises of a back and seating part and whereby said cushion further comprises heating elements which are steered by said heating control system.

Said fabric device will be provided with heating elements which allow heating of the fabric. In an embodiment said preferred heating elements are the heating elements as described in NL 1039218 which complete content is hereby incorporated by reference. Said heating elements may for instance be an electrical heating mat or pad. In a preferred embodiment, in the case that said fabric device is a cushion or a cover for a seat, said both the back and seat part will be provided with a separate heating element. The latter allows uniform heating of the entire cushion or cover. It also allows sequential heating (e.g. only the back part or the seating part) in case that should be desired by the user. Said heating elements may be incorporated in between the substrate or the various substrates of the fabric device.

The functioning of the heating elements present in the fabric device is steered by the heating control system according to the current invention. To that purpose, the heating elements are connected to the connectors of the signal transfer module of said heating control system.

By preference, said heating control system will be largely internalised in the substrate of the fabric device of the current invention. Such substrate may for instance be a foam chosen from a polyether foam, a foam rubber, a cold foam or a slow foam. It should be understood that the latter are mere examples, and that other material known in the art is equally possible. More in detail, the signal transfer module will be entirely internalised in the fabric device, e.g. located at the back or seat part. Wiring from and to the modules will be equally internalised in thereto provided compartment in the fabric device. For instance, if the fabric device is a cushion comprising a back and seating part, said back and seating portion will be provided by a channel, interconnecting both parts and suitable for receiving the electrical wiring. Said channel may be reinforced by a foam, or by any other material suitable in the art. In another embodiment, said channel will be formed by a flexible polymer. In yet another embodiment, said channel will be formed by a plastic material. By preference the channel will comprise openings, which may lead the relevant electrical wiring to the respective parts of the heating system (e.g. in the back portion or seating portion). Said channel will furthermore also provide openings to the exterior of said fabric device, in order to allow coupling of external devices, such as an external power supply.

The heat regulating module will by preference only partially be integrated in said fabric device in order to allow a user to (de)activate/regulate said system. To that purpose the heat regulating module will be attached to said fabric device by conventional means such as gluing or sewing/stitching.

If a flex circuit is used, attachment may preferably occur by means of stitching, the latter will preferably occur at the level of a seam of said fabric device. As such, said heat regulating module will become partially internalised at a seam of said fabric device. To that purpose, the flexible print plate of the heat regulating module is provided with one or more sewing areas as explained above. Said heat regulating module is attached to said fabric device by means of one or more stitches through said sewing area of the heat regulating module and the fabric device.

More in particular said heat regulating module will be sewn to the cushion fabric by two consecutive steps. In a first step, said cover a tissue fabric will be at the level of the seam of the fabric be sewn together by one sew in the transverse direction of said regulating module, thereby attaching the cover of heat regulating module with the fabric. The flexible print plate enwrapped by said cover will in this first step not be attached to the fabric, but will be correctly positioned. Both the front as well as the back of the heat regulating module will receive a stitch in the transverse direction as explained above.

In another embodiment, said print plate and cover will be attached by means of gluing or welding.

As a consequence, the heat regulating module will only partially be internalised in the fabric device. Ideally, that part of the heat regulating module that comprises the touch buttons for (de)activating/regulating said heating elements will be external and visible to the user. Also the part comprising the LED lights giving an indication of function and/or heat intensity will be visible. Preferably, the part comprising the CPU will be internalised in the fabric device. The latter minimises the chance that the CPU gets perturbed during use.

In a second step a partial stitch will be provided which will attach the flexible print plate to the cover and the fabric device. To that purpose, the three layers will be stitched together at the level of the stitch areas on the flexible print plate. Said stitch will be provided in the transverse direction of the heat regulating module. Said stitch will be restricted to the stitch area which is, as mentioned, devoid of any circuits. As such, perturbation of the entire system is prevented. Hence, said second stitch will be a discontinue stitch.

In a further embodiment, said fabric device will be provided with one or more sensors, e.g. a pressure sensor. In the case of a cushion or cover for a seat, such sensor can detect whether or not a person is present on said seat. In the case where there the pressure sensor does not detect a person seated on the device within a predefined time slot, it will send a signal to the signal transfer module which on its turn can steer the heating elements. The latter ensures the safety of the device and prevents overheating of an unused cushion as well as ensures economical use of the device by preventing unnecessary energy loss. In a further embodiment, said sensor may also be used to gather information on e.g. the degree of occupancy of a seat, for instance when a collection of cushions according to the current invention are being used, e.g. on café terrace, or in a sport stadium. Obviously the heating elements should be provided with adequate power supply means in order to activate the system. In an embodiment, said fabric device may be coupled to a general power supply by a cable. In a preferred embodiment, said fabric device is coupled to an external power supply, preferably a rechargeable power supply. To that purpose, said fabric device is preferably provided with power supply attaching means at the back portion of said fabric device.

Said power supply attaching means may comprise for instance a loop, a hook, buttons, Velcro or any other suitable means for attaching a battery to said fabric device. In an embodiment said power supply attaching means comprise a combination of an extension of said fabric device (e.g. a loop, or slot) and a hook, hanger, clasp, fastener, clip or hang-up. The latter is preferably made of a plastic or polymer.

In another embodiment, said power supply attaching means comprise an internalised compartment, such as a bag.

Said power supply is removably attached to said fabric device by the power supply attaching means or part of the power supply attaching means. In a preferred embodiment, said power supply comprises one or more batteries. Said any battery known in the art is possible such as a Ni—Zn, a LiFePO4 or a Li-ion battery. Preferably said battery is a Li-ion battery. A suitable battery may for instance be a 12 V or 24 V battery.

Preferably, said power supply is provided in a casing. The latter serves as a protective cover for the power supply as well as will enable the transfer of the current to the internal heating control system according to the current invention.

To that purpose, said casing may be provided with external electrical contacts. Said external electrical contacts of the casing correspond to external electrical contacts on said power supply attaching means. The word ‘corresponding’ in this context is to be understood as contacts with opposite polarity (hence: plus or minus). As such a transfer of power from the battery to the system may occur.

Preferably said external electrical contacts will have an odd number, such as 1, 3, 5, 7, 9 or 11. Preferably, said both the casing of the power supply and the power supply attaching means will be provided with on or three corresponding electrical contacts. The latter has as advantage that the battery casing can be attached to said power supply attaching means in a manner which is irrespective of the orientation of the battery. This is an advantage and increases the user-friendliness of the system.

Said casing will be preferably made from a polymer or plastic. In an embodiment, said casing comprises a lid which allows opening of the casing, e.g. for replacement of the battery or batteries inside. Said lid is preferably positioned along the longitudinal direction of the casing, but may for instance also be provided at the bottom of the casing. In another embodiment, said casing is open to one side.

Said casing may be provided with means for engaging with the power supply attaching means. In a preferred embodiment, the latter comprises a hook, a hanger or a loop which is engageable with the corresponding power supply attaching means. Said engagement occurs in a non-fixed and manually removable manner, e.g. by hanging or suspending the cover with power supply to the power supply attaching means. By engaging the two, an electrical connection will be automatically established by means of the electrical contacts present on both features. Said electrical connection will allow the transfer of the current to the internal heating control system according to the current invention (and hence subsequently, to the heating elements). To that purpose, said power supply is linked to said contacts of the casing by means of suitable electrical wiring. In a further embodiment, said power supply is connected to the electrical contacts by means of an intermediate, e.g. a print plate or circuit board. In the latter embodiment, said power supply means are connected to the print plate by means of electrical wiring from the power supply to the print plate. A second set of wiring runs from the print plate to the contacts present in the cover.
Additionally, wiring from the print plate is provided which connect said power supply to a second pair of electrical contacts on the casing (e.g. present on the bottom of the casing), whereby said second pair are connectable to power supply recharge means such as a battery charger. When the power supply means according to the current invention are empty or running low, said casing comprising the power supply means may be detached from the fabric device and placed on suitable power supply recharge means. In order to indicate the status of the power supply means, the system may be provided with indicators, such as LED lights. Suitable power supply means may for instance include a 48 multi-channel system allowing charging batteries in various states of discharge. Said maximal current range per channel may be 2.5 A output, whereby said maximal DC Voltage per channel may be between 35 and 40 V output.
Said corresponding contacts present in the power supply attaching means are connected with wiring leading inwards in the fabric device via the power supply attaching means. Said second set of wiring will connect the power supply with the heating control system. More preferably, said wiring is suitable for connecting the power supply to said power supply connector on said signal transfer module of the heating control system.

By the current set-up of the invention the amount of visible and outside wiring is reduced to an absolute minimum. The latter highly improves the safety requirements of the device and ensures good functioning by the device because the vulnerable parts of the system are kept without reach. Finally, because the visibility of the necessary wiring is kept to a minimal, the device will have a higher aesthetic value.

The casing according to the current invention may have any form which is suitable for receiving a power supply suitable to be used in conjunction with the current invention. In one embodiment, said casing will have a conical shape, whereby the cone at the top ends in the engaging means comprising the contacts. In another embodiment, said casing is rectangular.
The latter configuration provides for an optimal weight distribution of the battery supply when being connected to the power supply attaching means.

In a final aspect, the current invention relates to a seat comprising a cushion according to the current invention, and provided with power supply means according to the current invention.

The present invention will be now described in more details, referring to figures that are not limitative.

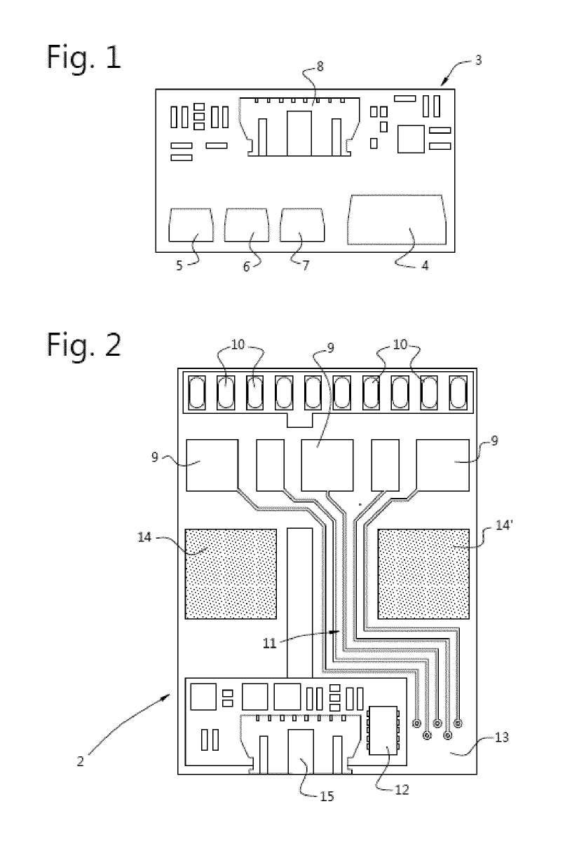

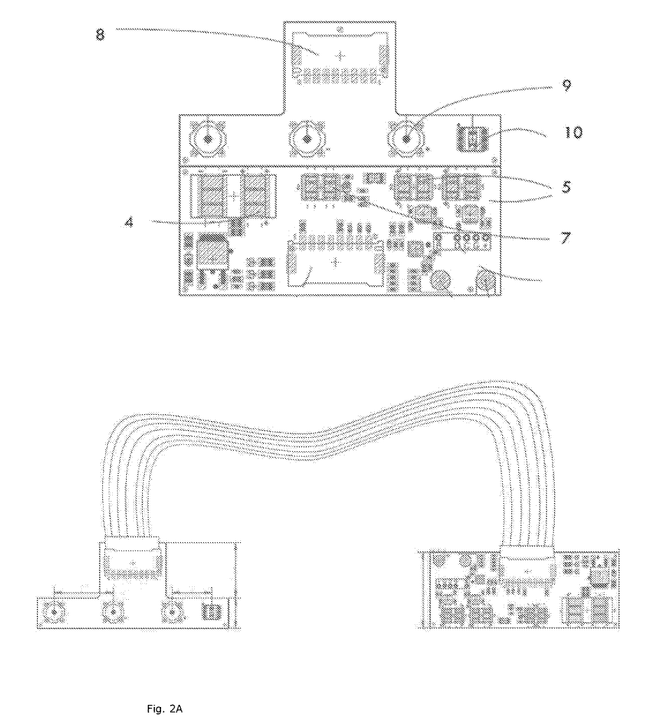

FIGS. 1 and 2 show possible embodiments of respectively a signal transfer module (3) and a heat regulating module (2) according to the current invention. FIG. 2A shows another embodiment of a heat regulating module (2) and a signal transfer module (3) according to the current invention. The signal transfer module (3) is a printed circuit board, comprising connectors for connecting the module (3) to various actors of the system. As shown in FIG. 1, the module (3) may comprise a connector (5) and (6) for connecting the module (3) with the heating elements in respectively back and seating portion of a cushion for a seat or any other fabric device which is suitable for receiving the currently described system. A third connector (7) may connect one or more (pressure) sensors present in the cushion. A last connector (4) can connect the power supply with the module (3). A connector for a pin cable (8) is provided for linking the signal transfer module (3) with the heat regulating module (2). Preferably said pin cable (8) is an eight pin cable. The module (3) may be further comprised of functional elements such as transistors, contacts, switches, circuits, etc. By preference, switching of the heating elements occurs by the presence of MOSFETS with low internal resistance. As a consequence, loses and therefore also heat production of the module are kept to a minimal.

The heat regulating module (2) as shown in FIG. 2 comprises a print plate (13). The module is comprised of touch areas (9) which serve to (de)activate or regulate the heating system upon being touched by a user. The module (2) further comprises one or more indicators (10) such as LEDs which can provide visual guidance to a user. Upon activating the heating system, the LEG lights will light up, indicating that the system is indeed active. Intensity of the heating can be regulated by means of the touch areas (lowering or increasing) which state will be directly reflected by the LED lights. Circuits (11) will run from the touch areas (9) to the CPU (12) present on the print plate (13). The print plate (13) is further provided with areas which are substantially devoid of any circuits or functional elements. These areas are the sewing areas (14, 14′). The print plate (13) shown in FIG. 2 comprises two sewing areas (14, 14′) which are positioned on opposite sides of the print plate (13). Preferably their function is indicated on the area itself, e.g. by symbols or words. The area on the print plate (13) comprising the CPU (12) is by preference reinforced on the back side by an epoxy layer (not shown). A connector (15) for a pin cable (16) is provided.

The microprocessor of the CPU (12) will read the touch areas (9) upon activation of one of them and will send two steering signals to the signal transfer module (3), which on its turn will activate two heating elements (one in the back portion and one in the seat portion of the cushion). Regulation of the power of a heating element may for instance be regulated by pulse-width modulation (PWM) with a frequency of 40 Hz. Preferably, the second heating element will be activated half a period later than the first element, in order to spread the load degree.

FIG. 2A shows a different embodiment of a heat regulating module (2) and a signal transfer module (3) according to the current invention. The heat regulating module (2) is comprised of a print plate (13) which is provided with a CPU (12), a LED indicator (10) and one or more buttons (9) for activating and regulating the system. The signal transfer module is provided with at least one connector for a heating element (6), a sensor connector (7), and a power connector (4). Both modules may be connected by means of a cable, such as a pin cable.

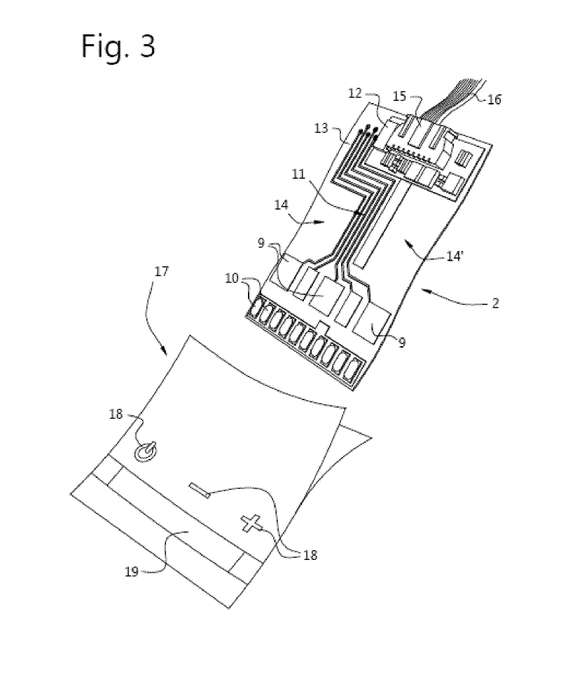

FIG. 3 shows a detail of the print plate (13) and a flexible cover (17) suitable for receiving the heat regulating module. The cover (17) will to that purpose be designed as an envelope, casing, sleeve or wrapper, comprising a back and front side which are at least partially attached to each other at the periphery, and which form an opening for receiving the print plate (13). The cover (17) is comprised of symbols or instructions (18) which location corresponds with the underlying touch areas (if said cover has received a print plate). The symbols or instructions serve to indicate the different functions of the system to the user. The cover may furthermore be provided with a see-through area or window (19), which is positioned above the indicators (LEDS) and which allows the passage of the visual signal produced by the indicators.

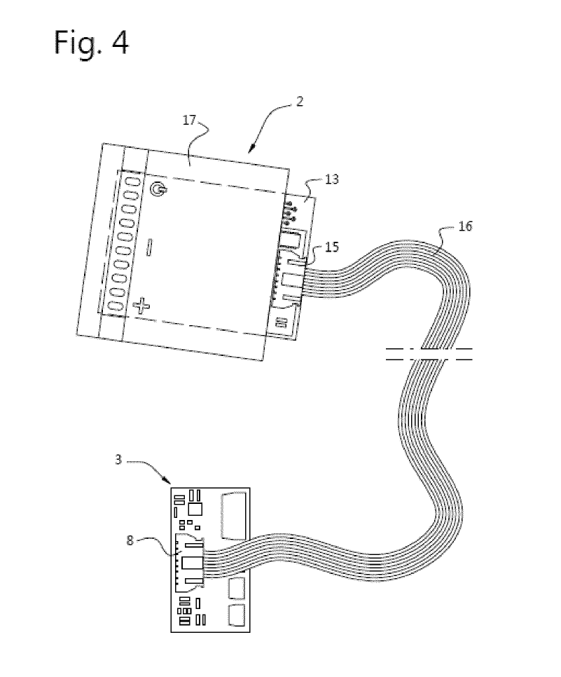

FIG. 4 shows a heating regulating system according to the current invention, whereby the print plate (2) is inserted in the cover (17) and which is connected to the signal transfer module (3) by means of a pin cable (16). Transfer module (3), pin cable (16) and part of the heat regulating module comprising print plate (13) and cover (17) will be inserted in the fabric device, e.g. a seat cushion. Only that part of the heat regulating module comprising the touch areas with the corresponding symbols on the cover will be outside the fabric and visible/reachable for the user.

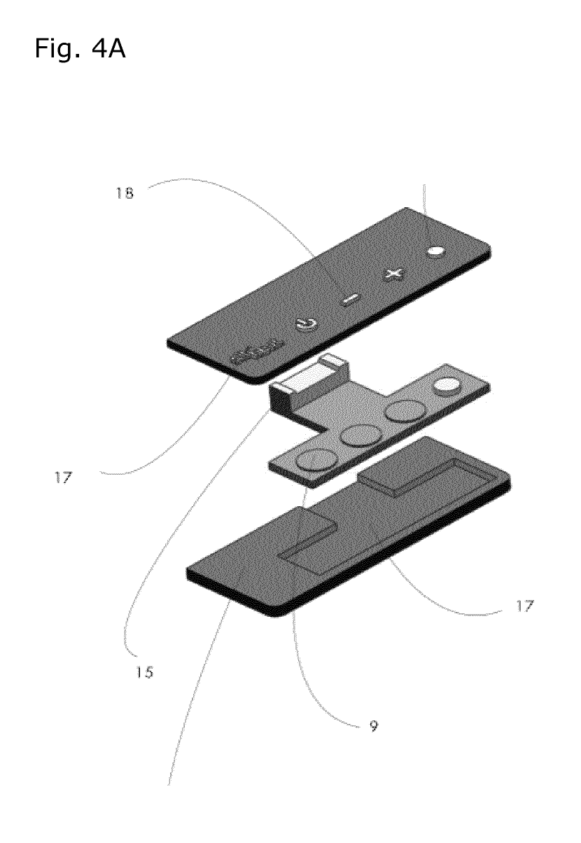

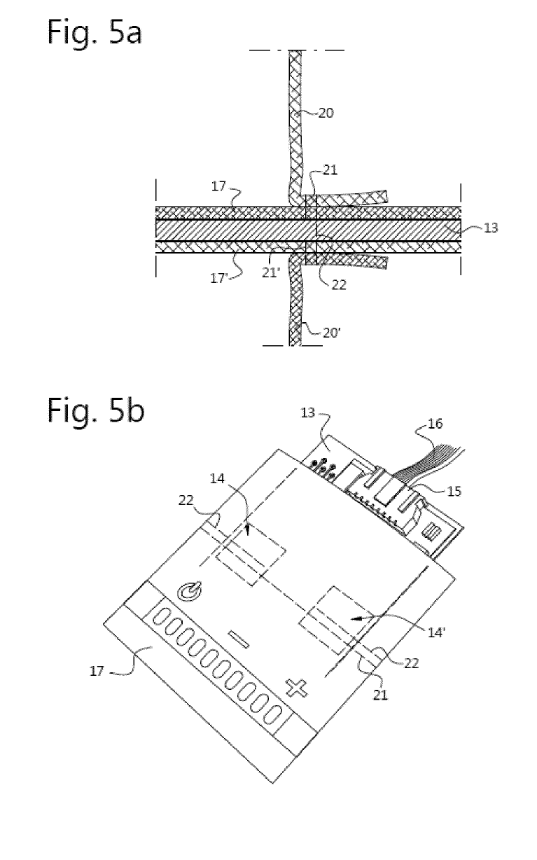

To that purpose the flexible cover (17) and print plate (13) may be sewn to the fabric device in a manner shown in FIG. 13. The print plate (13) is enveloped by the cover (17). The fabric (20) of the fabric device used for attaching the module to the fabric device will be located at the sewing area of the print plate. A first sew (21) will go through the fabric (20) and the layer (17) whereas the flexible print plate will remain untouched. The first sew will be provided at the upper side and the lower side. A second sew (22) will attach all layers as it goes through fabric, cover and flexible print. The second sew (22) will be a discontinuous sew as it is only located at the level of the sewing areas of the flexible print plate. FIG. 5A shows a cross-section of the heat regulating module (2) according to the current invention, attached to the fabric (20) of the fabric device (e.g. a cushion) by a first (21) and a second sew (22). FIG. 13b shows the location of the first (21) and second sew (22) on the cover. FIG. 5B shows the location of the sews on the cover.

FIG. 4A shows the cover (17) for the heat regulating module (2) as shown in FIG. 2A. A see-through area (1) is provided which will be positioned above a LED indicator (10). Symbols and/or instructions (18) are provided for allowing a user to operate the system. The cover (17) is provided with an indentation for receiving the module (2).

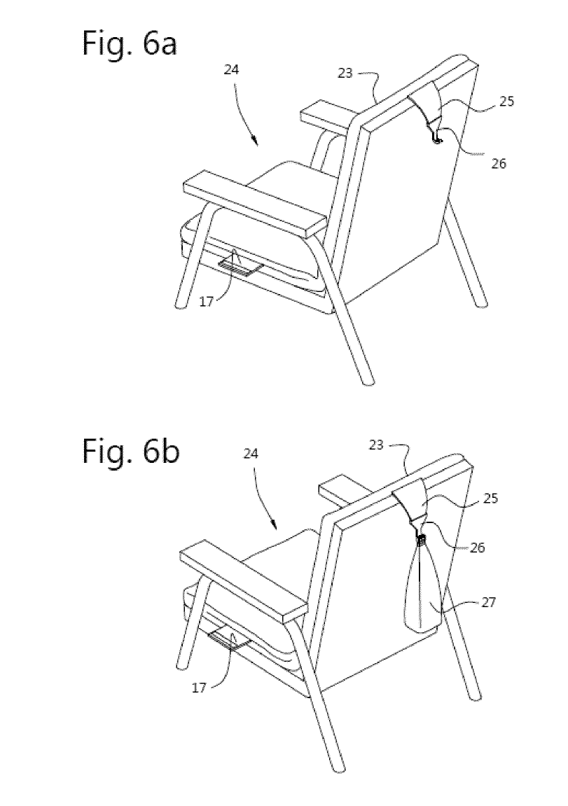

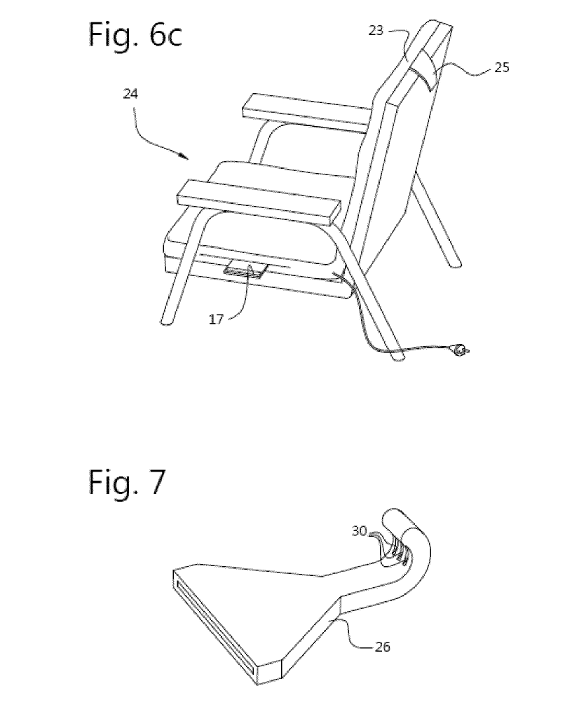

FIG. 6 A to C shows various embodiments of the current invention. FIG. 6A shows a seat (24) comprising a cushion (23) which is internally provided with heating elements steered by a heating control system according to the current invention. The embodiment shown in FIG. 6A shows an assembly which is not connected to any power supply. The fabric extension (25) of the cushion located at the back of the cushion will allow attachment of an external power supply. As shown on FIG. 6A, such fabric extension may comprise a loop. In the embodiment shown in FIG. 6B the extension is provided with an external power supply by means of a hook (26) attaching a power supply casing (27) to the fabric extension (25). In FIG. 6C an embodiment is shown which is connected to the electrical network, not to an external power supply.

FIG. 7 shows a detailed version of the power supply attaching means according to a possible embodiment of the current invention. The power supply attaching means comprise a hook (26) connectable to the fabric extension (25). Wiring from the hook will be led through the fabric to the signal transfer module internalized in the fabric. The distal end of the hook (26) is provided with electrical contacts (30) (which are connected internally with the wiring). The latter will serve to transmit the power received from the power supply to the system.

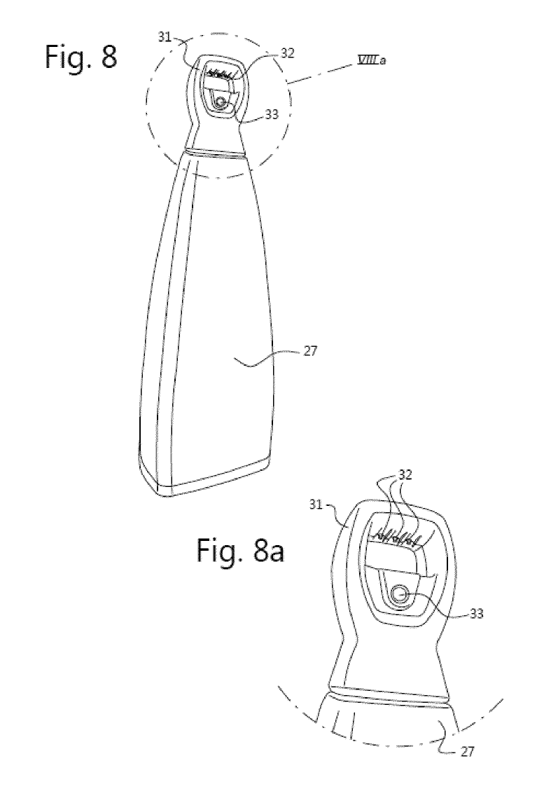

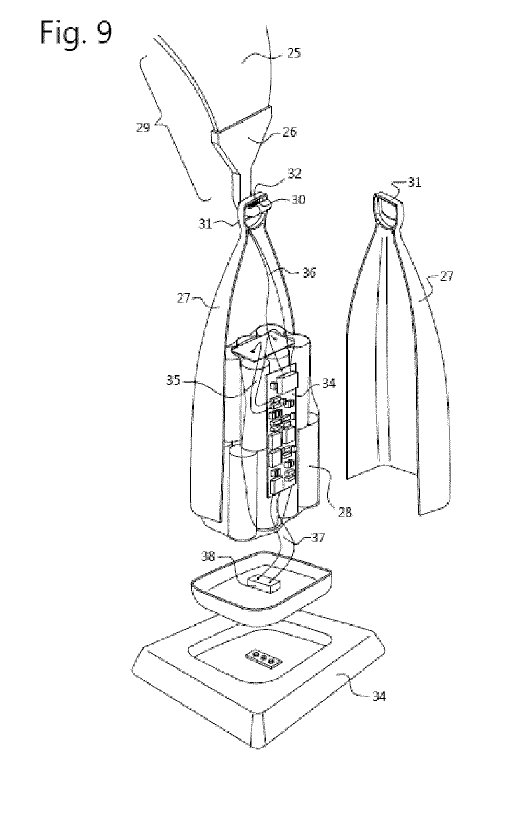

FIGS. 8 to 10 show schematic overview of the casing (27) and the power supply (28) suitable to be used in an embodiment of the current invention. The casing (27) is suitable for holding a battery or a plurality of batteries (28). To that purpose the casing may comprise of sub-parts whereby one part serves as a lid for opening the casing. FIG. 8 shows the casing (27) in closed configuration, with the power supply invisibly present in the casing. The casing (27) is substantially conical and ends at the distal end with means for engaging (31) with the hook of the power supply attaching means. The latter may be a hook as well or have an annular configuration (as shown on FIG. 8). The top of the ring is comprised with electrical contacts (32) which correspond to the contacts present in the hook of the power supply attaching means. As shown on the figures, 3 contacts will be present. A LED light (33) may be present on the casing to indicate the status of the internal power supply means. FIG. 8a shows a more detailed embodiment of the annular engagement means (31) with the electrical contacts (30) and the LED light (33). FIG. 9 shows an open casing with the power supply according to the current invention. The casing (27) is internally provided with power supply means (28) connected to the hook (26) of the power supply attaching means (29). The electrical contacts (30) of the hook (26) correspond with the electrical contacts (32) present in the annular engagement means (31) for transferring the power to the internal heating system.

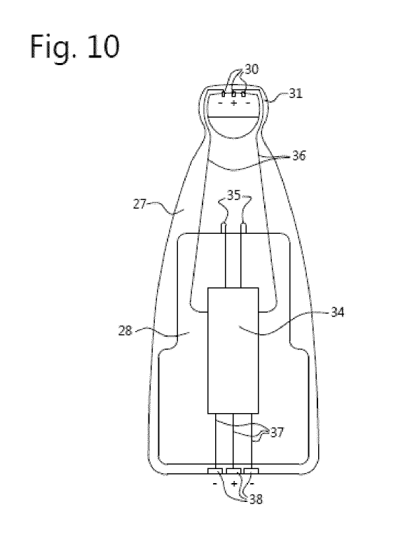

FIG. 10 shows a schematic overview of the inside of the casing provided with a power supply (28). The power supply (28) rests on the bottom of the casing is connected via wiring with a power supply circuit board (34). A second set of wiring will go from the circuit board (34) to the electrical contacts (30) present in the annular engagement means (31). A final third set of wiring (37) will run from the circuit board (34) to the bottom of the casing which is provided with contacts (38) suitable for recharging the power supply. To that purpose the casing (27) can be placed on power supply recharging means (39) as shown in FIG. 9.

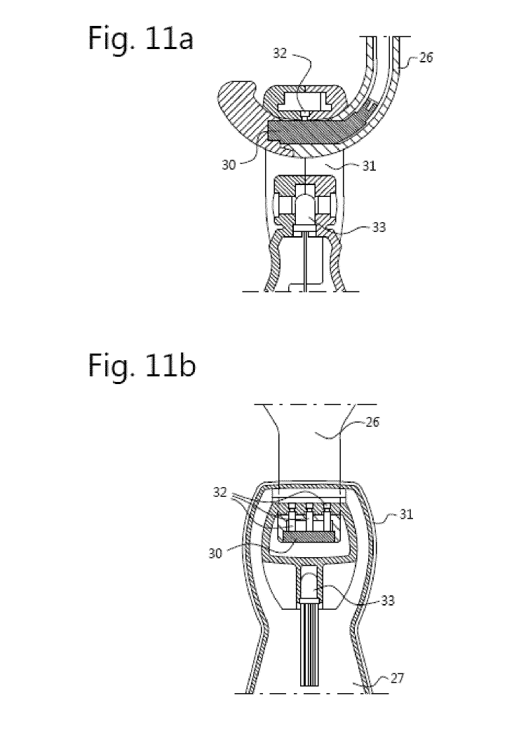

FIG. 11A and 11B show cross-sectional views of power supply attaching means (29) according to the current invention, engaged to the power supply (28) by the engagement means (31) of the casing (27). In the latter configuration, the corresponding electrical contacts (30, 32) present on the casing and the power supply attaching means are connected.

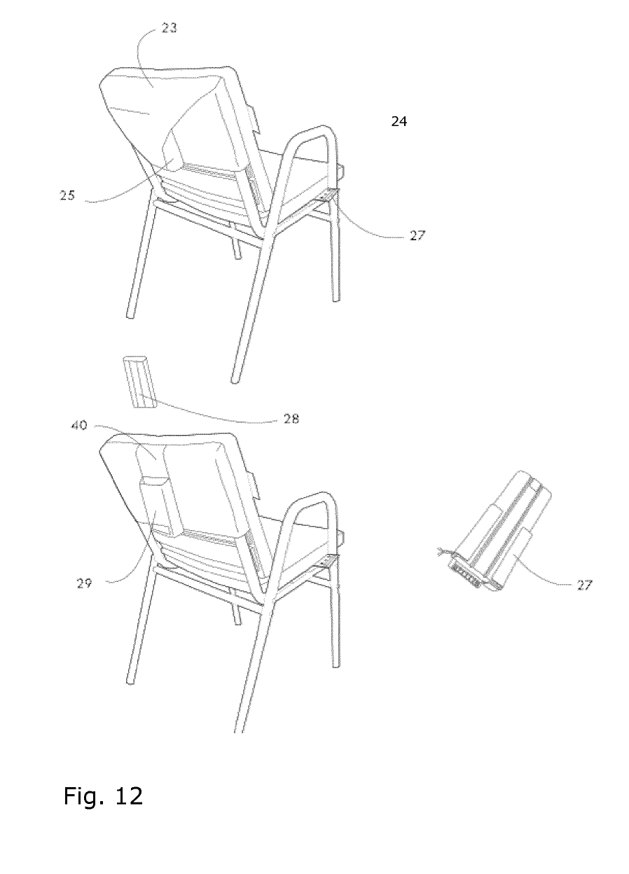

FIG. 12 shows other embodiments according to the current invention in which the power supply (28) is provided in an internalized compartment (25) which is an extension of the fabric (20). The power supply (28) is provided in a casing (127) which go into the compartment (25). A tunnel (40) in the fabric will allow a passage for the wiring of the system, which is to be connected to the power supply (28). As such, most of the system is internally provided in the seat.

### FEATURES PRESENT ON THE FIGURES

1 Heating control system
2 Heat regulating module
3 Signal transfer module
4 Connector for power supply
5 Connector for heating element
6 Connector for heating element
7 Connector for sensor
8 Pin cable connector
9 Touch area
10 Indicator
11 Circuits
12 CPU
13 Print plate
14,14′ Sewing area
15 Pin cable connector
16 Pin cable
17 Cover
18 Symbol
19 See-through area
20 Fabric
21 1st sew
22 2nd sew
23 Cushion
24 Seat
25 Extension
26 Hook
27 Casing
28 Power supply
29 Power supply attaching means
30 Electrical contacts
31 Engagement means
32 Electrical contacts
33 LED light
34 Circuit board
35 First set of wiring
36 Second set of wiring
37 Third set of wiring
38 Power supply recharging contacts
39 Power supply recharging means
40 Tunnel

1. Heating control system for regulating a heating system present in a fabric device, wherein said control system comprises a signal transfer module and a heat regulating module.

2. Heating control system according to claim 1, wherein said signal transfer module and heat regulating module are connected and wherein said heat regulating module comprises a print plate.

3. Heating control system according to claim 2, wherein said print plate comprises a control processing unit (CPU).

4. Heating control system according to claim 3, wherein said print plate comprises one or more touch areas for (de)activating and/or regulating said CPU.

5. Heating control system according to claim 2, wherein said print plate comprises one or more LED lights.

6. Heating control system according to claim 2, wherein said print plate is enveloped by a flexible cover, and wherein said flexible cover comprises symbols or instructions corresponding to said touch areas.

7. Heating control system according to claim 1, wherein said signal transfer module comprises connectors for connecting said module to a power supply, one or more heating elements and optionally a sensor system.

8. Fabric device for a seat, wherein said fabric device comprises a heating control system according to claim 1.

9. Fabric device according to claim 8, wherein said fabric device is internally provided with one or more heating elements, and wherein said heating elements are connected to connectors on said signal transfer module.

10. Fabric device according to claim 9, wherein back portion and seat portion of said fabric device is provided with one or more heating elements.

11. Fabric device according to claim 8, wherein said fabric device comprises power supply attaching means at the back portion of said fabric device.

12. Seat comprising a fabric device according to claim 8.

13. Seat according to claim 12, wherein said seat comprises a power supply, removably attached to said fabric device by said power attaching means, whereby said power supply is provided in a casing.

14. Seat according to claim 13, wherein said casing is provided with external electrical contacts, suitable for connecting said power supply to said power supply connector on said signal transfer module.

15. Seat according to claim 13, wherein said power supply is rechargeable.

16. The heat control system of claim 1 wherein the fabric device comprises a seat cushion.

17. The heat control system of claim 1 wherein the fabric device comprises power supply attaching means at the back portion of said fabric device.
